(19) United States
(12) Patent Application Publication
(10) Pub. No.: US 2024/0290715 A1
(43) Pub. Date: Aug. 29, 2024

(54) SEMICONDUCTOR INTEGRATED CIRCUIT DEVICE

(71) Applicant: Socionext Inc., Kanagawa (JP)

(72) Inventor: Yasuhiko MAKI, Yokohama-shi (JP)

(21) Appl. No.: 18/399,335

(22) Filed: Dec. 28, 2023

Related U.S. Application Data
(63) Continuation of application No. PCT/JP2021/025014, filed on Jul. 1, 2021.

(51) Int. Cl. H01L 23/528; H01L 23/522; H01L 25/065

(52) U.S. Cl. CPC H01L 23/5283; H01L 23/5226; H01L 25/0657; H01L 2225/06541

(57) ABSTRACT

In a semiconductor integrated circuit device, a first semiconductor chip includes: a buried power rail that supplies first power; and a power line that is provided in a layer above the buried power rail and supplies second power. The buried power rail receives supply of the first power from the back face of the first semiconductor chip via a first through electrode, and the power line receives supply of the second power from the back face of the first semiconductor chip via a second through electrode. The cross-sectional area of the second through electrode is greater than the cross-sectional area of the first through electrode.

### CROSS-REFERENCE TO RELATED APPLICATIONS

This is a continuation of International Application No. PCT/JP2021/025014 filed on Jul. 1, 2021. The entire disclosure of this application is incorporated by reference herein.

### BACKGROUND

The present disclosure relates to a semiconductor integrated circuit device having buried power rails (BPRs).

As a semiconductor integrated circuit has become higher in integration and lower in voltage with its miniaturization, it has become necessary to design the circuit with more attention paid to a power supply voltage drop (IR-drop) and power supply noise. For this reason, design of a power delivery network (PDN) for supply of power to a semiconductor integrated circuit is important.

U.S. Pat. No. 10,636,739 (FIG. 7) discloses a structure of a power delivery network in which buried power rails are formed in a buried interconnect layer embedded in a substrate of a semiconductor integrated circuit to supply power from the backside of the semiconductor integrated circuit via through silicon vias (TSVs).

In the configuration of the cited patent document, however, since power is supplied to the buried interconnect layer, the following problem arises. When it is intended to supply power to an interconnect layer located above the buried interconnect layer, the resistance value of the power delivery network increases, thereby increasing the power supply voltage drop. There also arises a problem that, when power is supplied from the buried interconnect layer to transistors, power supply noise having occurred in the transistors is liable to travel to an upper interconnect layer.

In particular, in a semiconductor integrated circuit device having semiconductor chips stacked one upon another, when power is supplied from a lower semiconductor chip to an upper semiconductor chip, the above problems of the power supply voltage drop and the power supply noise become significant for the power supplied to the upper semiconductor chip.

An objective of the present disclosure is providing a semiconductor integrated circuit device having buried power rails in which a power supply voltage drop and power supply noise can be prevented or reduced.

### SUMMARY

According to a mode of the present disclosure, a semiconductor integrated circuit device includes a first semiconductor chip, wherein the first semiconductor chip includes: a substrate; a first buried power rail formed in a buried interconnect layer in the substrate and supplying first power; and a first power line formed in a layer above the first buried power rail and supplying second power, the first buried power rail receives supply of the first power from a back face of the first semiconductor chip via a first through electrode, the first power line receives supply of the second power from the back face of the first semiconductor chip via a second through electrode, and the cross-sectional area of the second through electrode is greater than the cross-sectional area of the first through electrode.

According to the above mode, while the supply of the first power to the first buried power rail is performed from the back face of the first semiconductor chip via the first through electrode, the supply of the second power to the first power line formed in a layer above the first buried power rail is performed from the back face of the first semiconductor chip via the second through electrode. That is, the supply of the first power to the buried power rail and the supply of the second power to the first power line are implemented by different configurations. Therefore, power supply noise caused by transistors and the like related to the first power can be reduced for the second power. Also, since the cross-sectional area of the second through electrode is greater than the cross-sectional area of the first through electrode, the resistance value in the supply route of the second power can be reduced, whereby the power supply voltage drop can be prevented or reduced for the second power.

According to the present disclosure, in a semiconductor integrated circuit device having buried power rails, a power supply voltage drop and power supply noise can be prevented or reduced.

### BRIEF DESCRIPTION OF THE DRAWINGS

FIG. 1 shows the entire configuration of a semiconductor integrated circuit device according to an embodiment.

FIG. 2 shows a cross-sectional structure of the semiconductor integrated circuit device of FIG. 1.

FIGS. 3A-3B are plan views of a first semiconductor chip, where FIG. 3A shows its back face and FIG. 3B shows its principal face.

FIG. 4 shows a cross-sectional structure of Alteration 1 of the semiconductor integrated circuit device of FIG. 1.

FIG. 5 shows a cross-sectional structure of Alteration 2 of the semiconductor integrated circuit device of FIG. 1.

### DETAILED DESCRIPTION

An embodiment of the present disclosure will be described hereinafter with reference to the accompanying drawings.

### Embodiment

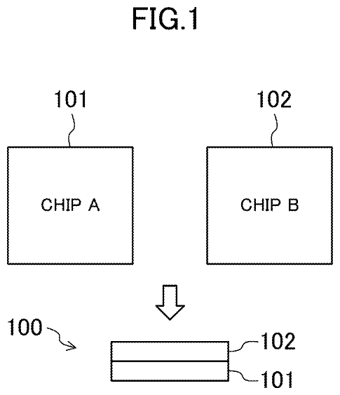

FIG. 1 is a view showing the entire configuration of a semiconductor integrated circuit device according to the embodiment. As shown in FIG. 1, a semiconductor integrated circuit device 100 is constituted by a first semiconductor chip 101 (chip A) and a second semiconductor chip 102 (chip B) stacked one upon the other. In the stack, the principal face of the first semiconductor chip 101 and the principal face of the second semiconductor chip 102 are opposed to each other.

In the first semiconductor chip 101, a circuit including transistors is formed, and also buried power rails supplying first power are formed. The first power is supplied from the back face of the first semiconductor chip 101. In the second semiconductor chip 102, power lines supplying second power are formed. The second power is supplied from the back face of the first semiconductor chip 101 to the second semiconductor chip 102 through the first semiconductor chip 101. For example, the first semiconductor chip 101 is a chip in which a logic circuit is mounted, and the semiconductor chip 102 is a chip in which a memory is mounted.

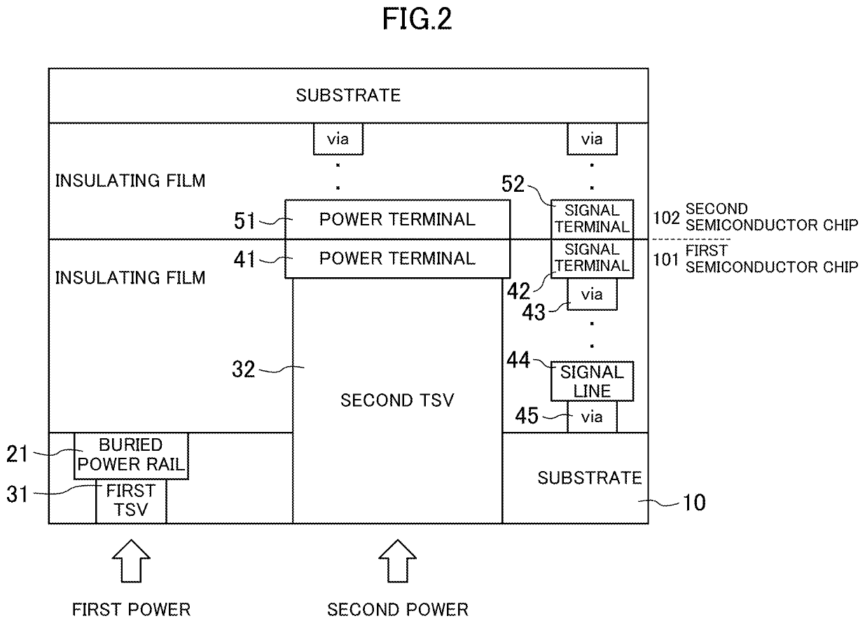

FIG. 2 is a view showing a cross-sectional structure of the semiconductor integrated circuit device 100 of FIG. 1. In FIG. 2, illustrated is a schematic cross-sectional structure related to power terminals and signal terminals of the semiconductor integrated circuit device 100.

In the first semiconductor chip 101, the first power and the second power are supplied from the back face. The first semiconductor chip 101 has a buried power rail 21 supplying the first power formed in a buried interconnect layer in a substrate 10. A first TSV 31 (corresponding to the first through electrode) is connected to the buried power rail 21 at one of its ends and exposed to the back face of the first semiconductor chip 101 at the other end. The buried power rail 21 is supplied with the first power from the back face of the first semiconductor chip 101 through the first TSV 31. The first power is then supplied to transistors and the like not shown from the buried power rail 21.

The first semiconductor chip 101 also has a power terminal 41 (corresponding to the first power line) formed in an uppermost interconnect layer. A second TSV 32 (corresponding to the second through electrode) is connected to the power terminal 41 at one of its ends and exposed to the back face of the first semiconductor chip 101 at the other end. The power terminal 41 is supplied with the second power from the back face of the first semiconductor chip 101 through the second TSV 32. That is, the power terminal 41 receives the second power bypassing the buried power rail. The power terminal 41 and the second TSV 32 have the same center position in planar view. Note that the center positions of the power terminal 41 and the second TSV 32 are only required to be roughly the same, not required to be exactly the same. The cross-sectional area of the second TSV 32 is greater than that of the first TSV 31.

The first semiconductor chip 101 also has a signal terminal 42 on the principal face. The signal terminal 42 is connected to transistors and the like not shown through vias 43 and 45, a signal line 44, and the like.

The second semiconductor chip 102 has a power terminal 51 and a signal terminal 52 formed on the principal face. The power terminal 41 of the first semiconductor chip 101 and the power terminal 51 of the second semiconductor chip 102, and the signal terminal 42 of the first semiconductor chip 101 and the signal terminal 52 of the second semiconductor chip 102, are joined together by hybrid bonding. The hybrid bonding is a technology in which, using a structure of having an insulating film formed around an electrode at the joining face of each chip, the mutually opposed electrodes, and the mutually opposed insulating films, are bonded together simultaneously. The method of bonding terminals is not limited to this, but other ways such as bonding with bumps may be used. In the second semiconductor chip 102, the second power supplied to the power terminal 51 is supplied to transistors and the like not shown through interconnects and vias.

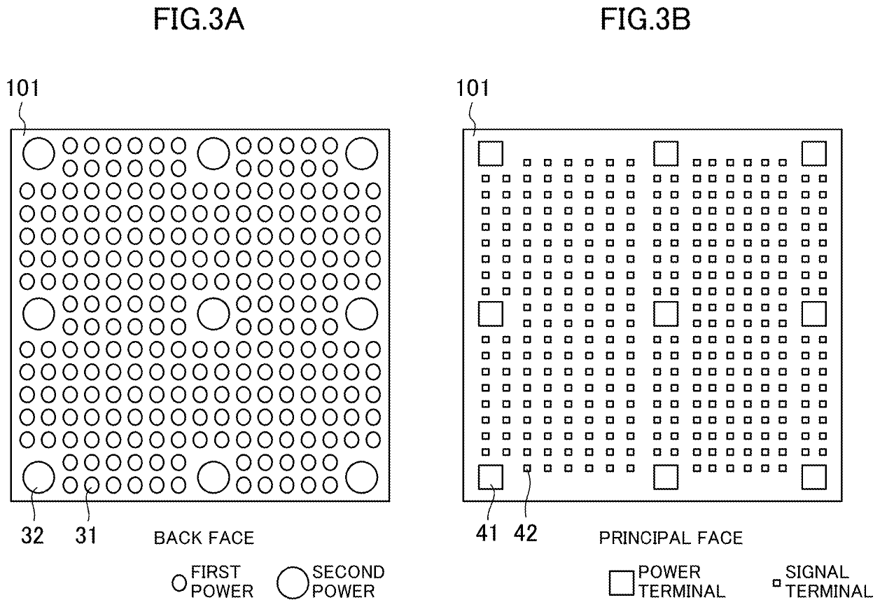

FIGS. 3A-3B are plan views showing a configuration of the first semiconductor chip 101, where FIG. 3A shows the back face and FIG. 3B shows the principal face.

As shown in FIG. 3A, openings for supplying the first power and openings for supplying the second power are provided on the back face of the first semiconductor chip 101, and the first TSVs 31 and the second TSVs 32 are respectively formed in the openings. The second TSVs 32 are greater than the first TSVs 31 in planar view. Note that, while the planar shapes of the first TSVs 31 and the second TSVs 32 are circular in FIG. 3A, the shapes are not limited to this.

As shown in FIG. 3B, the power terminals 41 and the signal terminals 42 are placed on the principal face of the first semiconductor chip 101. The power terminals 41 are located at the same positions as the second TSVs 32 formed on the back face in planar view. The power terminals 41 are connected to the power terminals 51 of the second semiconductor chip 102 placed at the opposed positions. The signal terminals 42 are connected to the signal terminals 52 of the second semiconductor chip 102 placed at the opposed positions. Note that, while the planar shapes of the power terminals 41 and the signal terminals 42 are square in FIG. 3B, the shapes are not limited to this.

Note that the quantities and placement positions of the first and second TDVs 31 and 32, the power terminals 41, and the signal terminals 42 shown in FIGS. 3A-3B are mere examples and are not limited to the illustrated ones.

According to this embodiment, advantages as follows are obtained. In the first semiconductor chip 101, the power supply to the buried power rails 21 and the power supply to the power terminals 41 in the upper interconnect layer are implemented by different configurations. That is, while the supply of the first power to the buried power rails 21 is performed through the first TSVs 31 from the back face of the first semiconductor chip 101, the supply of the second power to the power terminals 41 is performed through the second TSVs 32 from the back face of the first semiconductor chip 101. With this, power supply noise caused by transistors and the like related to the first power can be reduced for the second power supplied to the power terminals 41.

Also, the cross-sectional area of the second TSVs 32 that directly connects the power terminals 41 and the back face of the first semiconductor chip 101 is greater than the cross-sectional area of the first TSVs 31 that directly connects the buried power rails 21 and the back face of the first semiconductor chip 101. With this, since the resistance value in the supply route of the second power can be reduced, the power supply voltage drop can be prevented or reduced for the second power.

The advantages of reducing the power supply noise and preventing or reducing the power supply voltage drop in the second power described above are obtained more significantly in the configuration shown in this embodiment, i.e., the configuration in which the first and second semiconductor chips 101 and 102 are stacked one upon the other and the second power is supplied from the first semiconductor chip 101 to the second semiconductor chip 102.

Note that the configuration of this embodiment is easily applicable when the power supply to the first semiconductor chip 101 and the power supply to the second semiconductor chip 102 are different from each other.

### (Alteration 1)

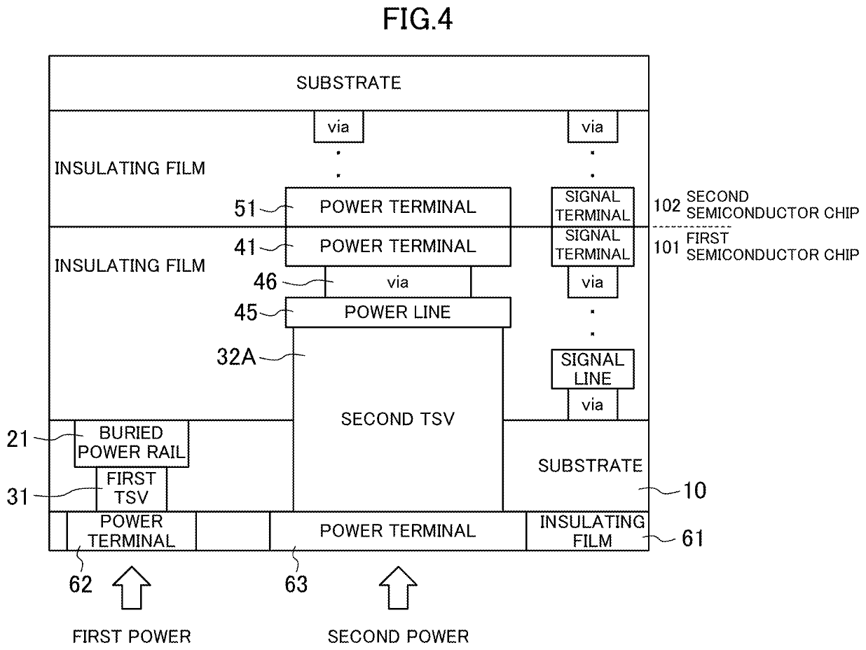

FIG. 4 is a view showing a cross-sectional structure of Alteration 1 of the semiconductor integrated circuit device 100 of FIG. 1. In FIG. 4, as in FIG. 2, illustrated is a schematic cross-sectional structure related to power terminals and signal terminals of the semiconductor integrated circuit device 100.

The cross-sectional structure shown in FIG. 4 is roughly the same as the cross-sectional structure shown in FIG. 2 except for the followings. In the first semiconductor chip 101, a second TSV 32A is not directly connected to the power terminal 41 (corresponding to the second power line), but connected through a power line 45 (corresponding to the first power line) and a via 46. The power line 45 is located above the buried power rail 21.

Also, an insulating film 61 is formed on the back face of the first semiconductor chip 101, and an interconnect layer is formed in the insulating film 61 to form power terminals 62 and 63. The first TSV 31 is connected to the power terminal 62, and the second TSV 32A is connected to the power terminal 63. The interconnect layer for formation of the power terminals 62 and 63 may be a single interconnect layer or may be made of a plurality of interconnect layers.

In this alteration, also, similar advantages to those in the above embodiment are obtained. That is, the power supply noise can be reduced, and the power supply voltage drop can be prevented or reduced, for the second power supplied to the power terminal 41.

### (Alteration 2)

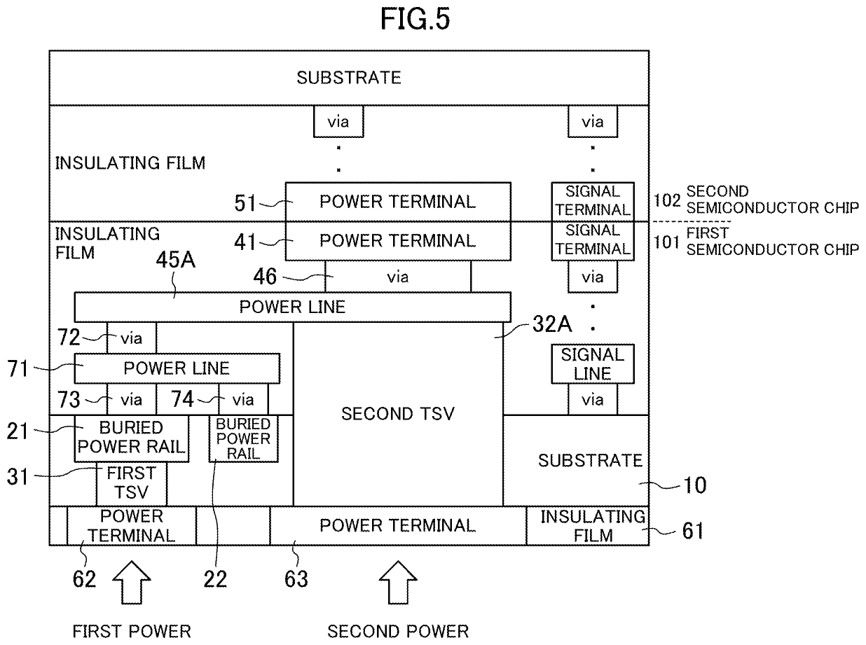

FIG. 5 is a view showing a cross-sectional structure of Alteration 2 of the semiconductor integrated circuit device 100 of FIG. 1. In FIG. 5, as in FIG. 2, illustrated is a schematic cross-sectional structure related to power terminals and signal terminals of the semiconductor integrated circuit device 100.

The cross-sectional structure shown in FIG. 5 is roughly the same as the cross-sectional structure shown in FIG. 4 except for the followings. In this alteration, the first power and the second power are the same in voltage. A power line 45A (corresponding to the first power line) connected to the second TSV 32A is electrically connected to the buried power rail 21 through a power line 71 and vias 72 and 73.

Also, a buried power rail 22 is formed in the buried interconnect layer in the substrate 10. The buried power rail 22 is connected to the buried power rail 21 through the power line 71, the via 73, and a via 74. The buried power rail 22 is not connected to the first TSV 31, receiving no supply of the first power from the back face of the first semiconductor chip 101.

According to this alteration, power supply is enhanced because the buried power rail 21 receives both the power supply through the first TSV 31 and the power supply through the second TSV 32A. Also, since the supply of the second power from the back face to the principal face of the first semiconductor chip 101 bypasses the buried power rail, the power supply noise can be reduced and the power supply voltage drop can be prevented or reduced.

According to the present disclosure, in a semiconductor integrated circuit device having buried power rails, a power supply voltage drop and power supply noise can be prevented or reduced. The present disclosure is therefore useful for improving the performance of a system LSI, for example.

1. A semiconductor integrated circuit device comprising a first semiconductor chip,
wherein
the first semiconductor chip includes:
a substrate;
a first buried power rail formed in a buried interconnect layer in the substrate and supplying first power; and
a first power line formed in a layer above the first buried power rail and supplying second power,
the first buried power rail receives supply of the first power from a back face of the first semiconductor chip via a first through electrode,
the first power line receives supply of the second power from the back face of the first semiconductor chip via a second through electrode, and
the cross-sectional area of the second through electrode is greater than the cross-sectional area of the first through electrode.

2. The semiconductor integrated circuit device of claim 1, further comprising
a second semiconductor chip stacked on the first semiconductor chip, a principal face of the second semiconductor chip being opposed to a principal face of the first semiconductor chip,
wherein
the second semiconductor chip receives supply of the second power from the first semiconductor chip through the first power line.

3. The semiconductor integrated circuit device of claim 1, wherein
the first semiconductor chip further includes
a second power line formed in a layer above the first power line and electrically connected to the first power line.

4. The semiconductor integrated circuit device of claim 1, wherein
the first power and the second power are the same in voltage, and
in the first semiconductor chip, the first buried power rail and the first power line are electrically connected to each other.

5. The semiconductor integrated circuit device of claim 1, wherein
the first semiconductor chip further includes
a second buried power rail formed in a buried interconnect layer in the substrate, the second buried power rail receiving no supply of the first power from the back face of the first semiconductor chip and being electrically connected to the first buried power rail.
